(19) United States
(12) Patent Application Publication
(10) Pub. No.: US 2003/0124809 A1
(43) Pub. Date: Jul. 3, 2003

(54) Method of forming an oxide film with resistance to erosion caused by stripper

(76) Inventor: Shyh-Dar Lee, Hsinchu Hsien (TW)

Correspondence Address: MERCHANT & GOULD PC, P.O. BOX 2903, MINNEAPOLIS, MN, 55402-0903, US

(21) Appl. No.: 10/155,552

(22) Filed: May 24, 2002

(30) Foreign Application Priority Data
Dec. 31, 2001 (TW) 90133441

(51) Int. Cl. H01L 21/336; H01L 21/3205; H01L 21/4763

(52) U.S. Cl. 438/305; 438/786; 438/787

(57) ABSTRACT

A method of forming an oxide film with resistance to erosion caused by a stripper during removal of a photoresist layer. First, a substrate is provided with a polysilicon gate layer. Then, using LPCVD, an LP-oxide film is formed on the substrate to cover the polysilicon gate layer. Then, using annealing treatment with a gas containing a nitrogen element, a surface layer with an oxynitride composition is formed on the oxide film.

### BACKGROUND OF THE INVENTION

1. Field of the Invention

The present invention relates to a method of forming an oxide film on a polysilicon layer and, more particularly, to a method of forming an oxide film with an oxynitride composition that has resistance to erosion caused by a stripper during removal of a photoresist layer.

2. Description of the Related Art

In the front end process of semiconductor device fabrication, especially for applications of non-volatile memory devices, an oxide film formed on the polysilicon layer serves as an important dielectric to contribute good electrical properties, such as lower leakage current and higher breakdown voltage, thus retaining the integrity of the stored data. However, the above-described good electrical properties are closely related to the flatness of the interface between the oxide film and the polysilicon layer. Conventionally, using thermal oxidation to directly grow the oxide film on the polysilicon layer by consuming polysilicon atoms, the interface between the oxide film and the polysilicon layer is coarse enough to cause high leakage current and low breakdown voltage. At present, using low-pressure chemical vapor deposition (LPCVD) to form an Oxide Oxide film on the polysilicon layer, a desired planarization is achieved on the interface between the Oxide film and the polysilicon layer. Thus, the Oxide film is commonly formed to protect the polysilicon from damages in subsequent processes.

Generally, using LPCVD to form the Oxide film, SiH₄ or TEOS are employed as precursors. However, during subsequent removal of a photoresist layer, the stripper comprising NH₄OH erodes the Oxide film, and even removes the Oxide film to expose the polysilicon layer. Seeking to solve this problem, one conventional method uses an LP—SiN film to replace the Oxide film to resist the erosion from the stripper. But, the induced stress of the LP—SiN film cannot match that of the polysilicon layer, resulting in leakage current. In the other conventional method, plasma treatment with N₂O, N₂ or NH₃ is additionally performed on the Oxide film to form a surface layer with O and N elements on the Oxide film, thus the oxynitride composition can have resistance to the erosion caused by the striper. Nevertheless, this creates a problem of plasma damage.

### SUMMARY OF THE INVENTION

The present invention provides a method of forming an oxide film that has resistance to erosion caused by NH₄OH in a stripper during removal of a photoresist layer.

The method of forming an oxide film is performed on a substrate with a polysilicon gate layer. First, using LPCVD, an LP-oxide film is formed on the substrate to cover the polysilicon gate layer. Then, using annealing treatment with a gas containing a nitrogen element, a surface layer with an oxynitride composition is formed on the oxide film.

Accordingly, it is a principal object of the invention to provide an LP-oxide film on a polysilicon layer to achieve low leakage current.

It is another object of the invention to provide an LP-oxide film on a polysilicon layer to achieve high breakdown voltage.

Yet another object of the invention is to provide an LP-oxide film with the oxynitride composition to resist NH₄OH in a stripper.

These and other objects of the present invention will become readily apparent upon further review of the following specification and drawings.

### BRIEF DESCRIPTION OF THE DRAWINGS

FIGS. 1 to 5 are sectional diagrams showing a method of forming an oxide film having resistance to erosion caused by a stripper during removal of a photoresist layer.

Similar reference characters denote corresponding features consistently throughout the attached drawings.

### DETAILED DESCRIPTION OF THE PREFERRED EMBODIMENTS

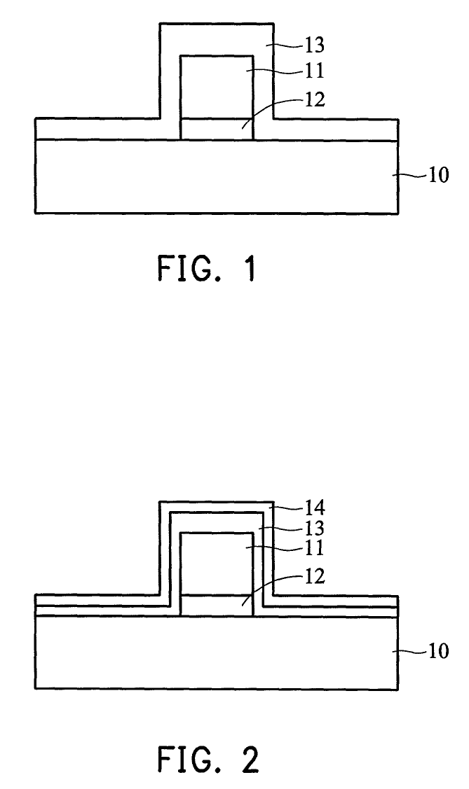

FIGS. 1 to 5 are sectional diagrams showing a method of forming an oxide film having resistance to erosion caused by a stripper during removal of a photoresist layer. As shown in FIG. 1, a silicon substrate 10 is provided with a gate oxide layer 11, a polysilicon gate layer 11 and an LP-oxide film 13. Preferably, the gate oxide layer 12 is grown by thermal oxidation at 900° C., and the polysilicon gate layer 11 is deposited by LPCVD with SiH₄ as the precursor. Thereafter, using photolithography and etching, the gate oxide layer 12 and the polysilicon gate layer are patterned on the silicon substrate 10. Then, using LPCVD with TEOS (tetra-ethyl-ortho-silicate) or SiH₄ as the precursors, the LP-oxide film 13 is deposited on the entire surface of the silicon substrate 10 to cover the polysilicon gate 11. Preferably, the LP-oxide film 13 is silicon oxide of 300 Å thickness.

Next, as shown in FIG. 2, using annealing with gas containing the nitrogen element, such as N₂, NH₃ and N₂O, the nitrogen element and the oxygen element in the LP-oxide film 13 are chemically reacted to form a surface layer 14 with the oxynitride composition. The annealing treatment is performed at 450˜750° C. (650° C. is preferred) for 30˜60 minutes.

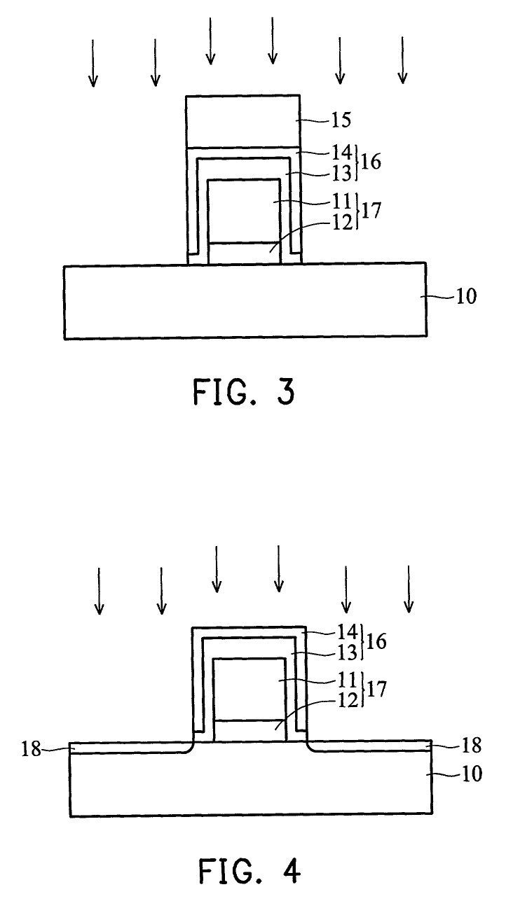

Next, as shown in FIG. 3, a photoresist layer 15 is provided on the silicon substrate 10, and then the photoresist layer 15 is patterned by photolithography and etching, thus the patterned photoresist layer 15 covers the polysilicon gate layer 11. Then, using dry etching with the patterned photoresist layer 15 as a mask, the exposed portions of the LP-oxide film 13 and the surface layer 14 are anisotropically etched to serve as an offset spacer 16 on the sidewall 17 of the polysilicon gate layer 11 and the gate oxide layer 12.

Next, as shown in FIG. 4, the patterned photoresist layer 15 is removed by a stripper. Since the surface layer 14, having the oxynitride composition, resists NH₄OH in the stripper, an erosion possibly caused by the stripper is avoided. Thereafter, using ion implantation with the offset spacer 16 as a mask, As ions, P ions or B ions are introduced into the silicon substrate 10 to serve as a source/drain extension region 18. To tune the threshold voltage of the gate layer, the source/drain extension region 18 has a low concentration of implanted ions.

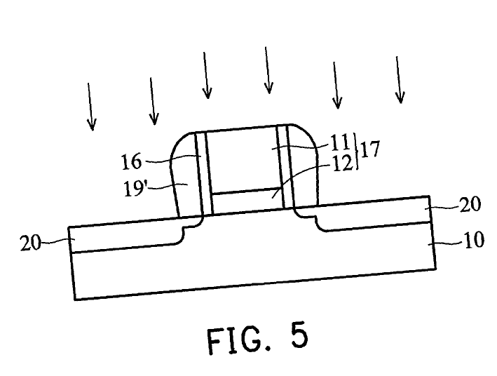

Next, as shown in FIG. 5, using LPCVD, an LP-oxide film of approximate 300 Å thickness is deposited on the entire surface of the silicon substrate 10. Then, using anisotropical etching, parts of the LP-oxide layer and offset spacer 16 are removed to expose the top of the polysilicon gate layer 11 and the silicon substrate 10. Thus, the remainder of the LP-oxide layer on the offset spacer 16 on the sidewall 17 serves as an insulating spacer 19′. Finally, using ion implantation with the offset spacer 16 and the insulating spacer 19′ as a mask, As ions, P ions or B ions are introduced into the exposed areas of the source/drain extension region 18 to serve as a source/drain region 20.

It is to be understood that the present invention is not limited to the embodiments described above, but encompasses any and all embodiments within the scope of the following claims.

What is claimed is:

1. A method of forming an oxide film, comprising steps of:
providing a substrate having a polysilicon gate layer;
depositing an oxide film on the substrate to cover the polysilicon gate layer; and
using annealing treatment with a gas containing a nitrogen element to form a surface layer on the oxide film.

2. The method according to claim 1, wherein the substrate is a silicon substrate.

3. The method according to claim 1, wherein the oxide film is deposited by low-pressure chemical vapor deposition (LPCVD).

4. The method according to claim 1, wherein the gas containing a nitrogen element is N₂, NH₃ or N₂O.

5. The method according to claim 1, wherein the surface layer comprises an oxynitride composition.

6. The method according to claim 1, wherein the annealing treatment is performed at 450˜750° C. for 30˜60 minutes.

7. A method of forming an oxide film on a substrate having a gate structure, comprising steps of:
depositing an oxide film on the substrate to cover the gate structure;
using annealing treatment with a gas containing a nitrogen element to form a surface layer on the oxide film;
forming a photoresist layer having a pattern on the oxide film;
etching the oxide film with the photoresist layer as a mask, in which the oxide film remaining on the sidewall of the gate structure serves as an offset spacer; and
removing the photoresist layer with a stripper.

8. A method according to claim 7, further comprising, after removal of the photoresist layer, steps of:
using ion implantation to form a source/drain extension region adjacent to the offset spacer in the substrate;
forming an insulating spacer on the offset spacer; and
using ion implantation to form a source/drain region in the exposed are of the source/drain extension region in the substrate.

9. The method according to claim 7, wherein the substrate is a silicon substrate.

10. The method according to claim 7, wherein the gate structure comprises a gate oxide layer and a polysilicon gate layer.

11. The method according to claim 7, wherein the oxide film is deposited by low-pressure chemical vapor deposition (LPCVD).

12. The method according to claim 7, wherein the gas containing a nitrogen element is N₂, NH₃ or N₂O.

13. The method according to claim 7, wherein the surface layer comprises an oxynitride composition.

14. The method according to claim 7, wherein the ion implantation introduces P ions, As ions or B ions.

15. The method according to claim 7, wherein the annealing treatment is performed at 450˜750° C. for 30˜60 minutes.
